(19) United States
(12) Patent Application Publication
(10) Pub. No.: US 2026/0269579 A1
(43) Pub. Date: Sep. 10, 2026

(54) AN ELECTRICAL CONDUCTOR WITH INTEGRATED HEAT SINK

(71) Applicant: KK Wind Solutions A/S, Ikast (DK)

(72) Inventors: Poul Thing, Ikast (DK); Jorgen Dahl Vestergaard, Kibaek (DK); Bjorn Rannestad, Aalborg (DK)

(21) Appl. No.: 19/167,377

(22) PCT Filed: Mar. 22, 2024
(86) PCT No.: PCT/DK2024/050067

§ 371 Date: Sep. 21, 2025

(30) Foreign Application Priority Data
Mar. 28, 2023 (DK) PA202370156
Apr. 27, 2023 (DK) PA202370206
May 26, 2023 (DK) PA202370261

(51) Int. Cl. H02B 1/56; H05K 7/20

(52) U.S. Cl. CPC H02B 1/565; H05K 7/2039

(57) ABSTRACT

An electrical conductor includes at least one first terminal and at least one second terminal spaced apart by a middle segment configured to support conductance of an electric current between the at least one first terminal and the at least one second terminal. The middle segment includes at least one integrated heat sink.

### FIELD OF THE INVENTION

The invention relates to an electrical conductor comprising an integrated heat sink, an electric system comprising such electrical conductor and a method of cooling a power electronic component by such electrical conductor.

### BACKGROUND OF THE INVENTION

In the art it is known e.g. from US20230105637 to equip power modules with heat sinks as a way to transfer heat from the power module to its surroundings. US20230105637 represent a whole range of variants of mounting a heat sink to a power module. Typically, known heat sinks are made of aluminium blocks with fins that are thermally connected to the power module. A fan then ensures to provide an air flow passing the fins and thereby removing the heat.

A problem with known heat sinks is that they are typically large compared to the component from which they are removing heat. Thus, a problem with the prior art is to remove heat from a component with a reduced size of a heat sink without compromising operation range and life time of the component. These problems are solved by the present invention as described below.

### SUMMARY OF THE INVENTION

The inventors have identified the above-mentioned problems and challenges related to removal of heat in an electric system and solved these problems by the present invention as described below.

In an aspect, the invention relates to an electrical conductor comprising at least one first terminal and at least one second terminal spaced apart by a middle segment configured to support conductance of an electric current between said at least one first terminal and said at least one second terminal, characterized in that it said middle segment comprises at least one integrated heat sink.

A middle segment comprising an integrated heat sink is advantageous in that not only does such electrical conductor facilitate improved cooling of the electrical conductor itself, e.g. when used as a high-power busbar for conducting currents to or from a component to which it is connected. But such middle segment advantageously also enabling cooling of a component such as a power electronic component such as a power module by mounting the power modules with a thermal connection to the electrical conductor with an integrated heat sink. Thereby eliminating or reducing the need of separate heat sinks for the power module.

The heat sink may provide a larger surface area of the electrical conductor where it is located compared to other parts of the electrical conductor where no heat sink is located.

In addition, or alternatively a heat sink may provide a more open surface of the electrical conductor, particularly of the middle segment, compared to parts of the electrical conductor which have no heat sink.

It should be mentioned that a heat sink may be made of two or more materials and thus the conductor and the heat sink could be referred to as polylithic. Hence, despite two materials a polylithic conductor with heat sink is still composed of the two materials without joints or seams.

In an exemplary embodiment of the invention said at least one heat sink is removably attached to said middle segment of said electrical conductor.

This is advantageous in that it has the effect, that it is possible to adjust the position of the heat sink on the electrical conductor. Thus, it is possible to adjust heat sink capacity directly to a hot spot e.g. of an electrical component or an area which need cooling by airflow.

In fact, it may be possible during operation of an electrical system to establish a thermography of the electrical system and based on an evaluation of the resulting picture adjust or position one or more heat sinks to increase cooling at relevant areas.

In an exemplary embodiment of the invention, said at least one heat sink is an integrated part of said middle segment of said electrical conductor.

An integrated heat sink is advantageous in that it has the effect, that no additional components are needed to remove heat from a heat generating component.

In an exemplary embodiment of the invention, said electrical conductor comprises integrated fan fastening points.

This is advantageous in that it has the effect that a fan can be mounted directly to the electrical conductor. Preferably directly above an integrated heat sink e.g. of the middle part of the electrical conductor. Thus, a flow of cooling air may be generated by a fan directly towards the heat sink of the electrical conductor, towards an additional heat sink, towards an electrical component, etc.

In an exemplary embodiment of the invention, said integrated heat sink is formed by an electrically conductive material of said middle segment.

This is advantageous in that the electrical conductor itself becomes a heat transferring is the heat sink. I.e. at least the middle part of the electrical conductor has a dual purpose of transferring heat from a component and conducting current to or from a component.

In an exemplary embodiment of the invention, said integrated heat sink is said middle segment of said electrical conductor, wherein said middle segment is at least partly manufactured with an air penetrating geometry.

An air penetrating geometry is advantageous in that a flow of cooling fluid such as air is allowed to flow between conductor branches of the electrical conductor. Thereby is obtained a better transfer of heat from the individual conductor branches and from the heat generating component connected there to.

In an exemplary embodiment of the invention, said air penetrating geometry is selected from the list comprising: gyroid-like design, branch-like design, bionic design, web-like design, honeycomb design and spongy design.

Designs like the mentioned are advantageous in that a cooling air flow is able to enclose the electrical conductor. Further, these designs may comprise or be designed with air guides for guiding the cooling air flow towards a desired hot spot of a heat generating component air. In this way heat may be effectively removed from large areas surrounding the electrical conductor.

In an exemplary embodiment of the invention, said first terminal is comprised by a first end and second terminal is comprised by a second end, wherein said heat sink is integrated in said first end or in said second end.

Having a heat sink at the surface of the ends of the electrical conductor is advantageous in that heat generated at the connection between the terminals of the electrical conductor and an electrical component to which it is connected can be removed. In this and similar situations, an integrated heat sink is advantageous over known ways of removing heat such as simple extending the ends of the electrical conductor to establish more area of the conductor. By the heat sink of the present invention, the same areas or even a larger area can be provided with less material and at the same time without compromising the free space needed for mounting the electrical conductor to the electrical component.

In an exemplary embodiment of the invention, said middle segment with said integrated heat sink is one monolithic geometry.

A monolithic geometry is advantageous in that the middle segment including an integrated heat sink is manufactured in one piece. This may be achieved by moulding, printing, extrusion, etc. Thereby, no additional parts are needed and thus, no additional mounting and assembling are needed leading to a reduction in possible sources of errors.

In an exemplary embodiment of the invention, said monolithic geometry comprises one or more protrusions or one or more recesses.

In an exemplary embodiment of the invention, said one or more protrusions are monolithically integrated with said middle segment as one or more outgrowing cooling fins.

Protrusions/outgrowths are advantageous in that they increase the area of the electrical conductor where a flow of cooling fluid is able to remove heat. More specifically, the area is increased by using a minimum of material.

In an exemplary embodiment of the invention, said middle segment is thermally connected with a heat generating component wherein said thermal connection is at a physically location on said heat generation component which is different from the physical location on said heat generating component that is electrically connected to said electrical conductor.

This is advantageous in that it has the effect that heat can be transferred from the component to the conductor and thus to the ambient via the heat sink. More specific heat may be removed from the component at a location of the component that is different from the location where the conductor is connected to the component. This is also true if the conductor comprising the heat sink is also the conductor which is electrically connected to the component.

In an exemplary embodiment of the invention, said integrated heat sink is connected directly with said heat generating component.

This is possible if the phase of the conductor comprising the heat sink is the same as is supplying the component. This is advantageous in that no additional components are needed. With this said a thermal conductive paste may be used to ensure that no air pockets are present in the thermal path between heat sink of conductor and component. The conductor may be fastened to the component with screws, adhesives, cold spray, etc.

In an exemplary embodiment of the invention, said electrical conductor is configured to supply power to a component and wherein said middle segment comprising said integrated heat sink is configured to remove heat from said component via said integrated heat sink.

This is advantageous in that it has the effect that the electrical conductor has a dual function i.e. the function of supplying power to the electrical component and the function of removing heat from the electrical component. By during the latter via the integrated heat sink this function is improved significantly compared to known electrical conductors which has no means for removing heat other than its planer surface which is not optimized for heat removal.

In an exemplary embodiment of the invention, said middle segment is thermally connected with a heat generating component via an additional heat sink.

Inserting an additional heat sink between the component and the electrical conductor is advantageous in that it has the effect that a minimum distance between the component and the conductor is established. This minimum distance may be a requirement form the producer of the electrical component to protect electronics, switches, etc in the component.

Preferably, it is a part of the middle segment comprising an integrated heat sink that is connected to the additional heat sink. The additional heat sink may be screwed to the conductor and to the component, it may be fastened by a pivotable clamp fixed to the additional heat sink or the conductor and secured on the component.

In an exemplary embodiment of the invention, said additional heat sink is at least partly manufactured in a non-current conducting material.

This is advantageous in that it has the effect that by inserting such non electrically conducting heat sink, galvanic isolation is obtained and at the same time a controlled flow of air can be provide for removing heat from the component. As an example, the additional heat sink may be of a ceramic material, plastic/polymer, etc.

Thus, the additional heat sink may guide a flow of air so that the air flow is passing by e.g. a backplate of the electrical conductor and passing by the integrated heat sink of the electrical conductor. The flow may be generated by a fan that may be positioned/connected to the additional heat sink or the electrical conductor.

Heat sinks in the form of protrusions or outgrowths are advantageous in that in addition to guiding heat away from the conductor, they may also be used for guiding a flow of air in a predetermined direction.

In an exemplary embodiment of the invention, said middle segment with integrated heat sink is located in an electrical cabinet at a location of a cold spot.

A cold spot should be understood as a location inside an electrical cabinet where a flow of cooling air is higher than other locations. A cold spot could be established e.g. by installing air guides strategic inside the electrical cabinet and thereby guide a flow of air, which may be provided by a fan, towards one side, middle section or the like. A cold spot could also be established by cabinet layout i.e. location of components creating flow paths inside the cabinet or by location of fan, heat exchanger, piping etc. Hence, in such cold spot it may be advantageous to locate a heat sink of an electrical conductor due to the high flow of cooling fluid such as cooling air.

In an exemplary embodiment of the invention, said middle segment with integrated heat sink is located in an electrical cabinet at a location of a hot spot.

A hot spot could be understood as a location inside an electrical cabinet where more heat is generated than other locations. A hot spot is typically at an electrical component such as a busbar, a power module, a reactor, etc. It is advantageous to connect a part, such as the middle segment, of an electrical conductor comprising a heat sink thermally to such heat generating electrical component.

Thermally connection may be understood as a direct connection between the integrated heat sink and the heat generating component, a connection via a thermal paste via an additional heat sink, or the like.

In an exemplary embodiment of the invention, said at least part of said middle segment and said integrated heat sink is at least partly manufactured simultaneously by an additive manufacturing process.

Manufacturing an electrical conductor according to the present invention by an additive manufacturing process is advantageous in that the ends and middle segment including integrated heat sinks may be monolithically formed. This is advantageous in that it has the effect, that the integrated heat sink are perfectly secured to the middle segment and thus the risk of them falling off is reduced significantly.

In an exemplary embodiment of the invention, said middle segment is monolithically formed in an electrically conductive material.

Thus, independent of geometry, the middle segment is one piece which is advantageous in that it has the effect, that no need to manually connect middle segment parts. Thereby is mounting speed of the electrical system in which the electric conductor is mounted increased and at the same time risk of human errors are reduced if not eliminated with respect to assembling of the electrical conductor.

A one-piece middle segment may be manufactured by an additive manufacturing process, a moulding process, extrusion process or similar.

In an exemplary embodiment of the invention, said middle segment is monolithically formed in a first end with said first end of said electrical conductor and monolithically formed in a second end with said second end of said electrical conductor.

In an exemplary embodiment of the invention, said middle segment comprising a plurality of conductor branches.

One conductor branch may be designed and subsequently produced in a harmonica-like shape, spiral-like shape, etc. leading to a plurality of airgaps between parts of the same or neighbouring conductor branch.

It should be mentioned that a high-power electrical conductor may be built from a mix of conductor branches of different geometries.

In an exemplary embodiment of the invention, said electrical conductor has a resonance vibration frequency of at least 5 Hz, for example at least 20 Hz, for example at least 30 Hz, for example at least 70 Hz, for example at least 150 Hz for example at least 300 Hz, for example at least 500 Hz.

The electrical conductor is advantageously designed and subsequent manufactured so that it has a resonance vibration frequency associated with relative motion between the first end segment and the second end segment that is does not coincide with a natural frequency of the system in which it is included. This is to avoid vibrations initiated by natural frequencies from such electric system or mechanical system. An example of a mechanical system is a wind turbine which may have a natural frequency of 5 Hz.

An electrical conductor according to any of the above paragraphs manufactured by a method describe in the following paragraphs.

In an aspect, the invention relates to a method of cooling a power electronic component by physically connecting said power electronic component to an electrical conductor wherein said electrical conductor comprises a middle segment with a monolithic integrated heat sink, wherein said method comprises the step of providing a flow of air passing by said integrated heat sink.

In an exemplary embodiment of the invention, said air flow is generated by a fan.

Removing heat from a component via a heat sink which is an integrated part of an electrical conductor is advantageous in that it has the effect, that the need for external/additional heat sink(s) is eliminated. In this way the area of the electrical conductor and thus the material of the electric conductor have the dual purpose of conducting removing heat from a component and supplying a component with current. The same electrical conductor may both act as heat sink and power supply to the same component.

In an aspect, the invention relates to a high-power electrical system comprising
an electrical cabinet comprising an air inlet and an air outlet,
a plurality of electrical conductors wherein at least one of said plurality of electrical conductors comprise a first end, and
at least one heat generating component comprised by said electrical cabinet,
   wherein at least one of said plurality of electrical conductors comprises at least one integrated heat sink,
   wherein said heat sink is thermally connected to said at least one heat generating electrical component at a first location of said at least one heat generating electrical component,
   wherein said first end of said electrical conductor is electrically connected to said at least one heat generating electrical component at a second location of said at least one heat generating electrical component, wherein said first location and said second location are different locations.

A system comprising electrical conductors with integrated heat sinks is advantageous in that it has the effect, that the need for external heat sink is eliminated or reduced, thereby the system is more compact, cheaper and may be faster to mount.

In an exemplary embodiment of the invention, a fan is configured to establish a flow of air between an air inlet and an air outlet, and wherein at least one of said plurality of electrical conductors comprises a middle segment in which said integrated heat sink is located, and wherein said integrated heat sink is located in said flow of air.

An electrical conductor may comprise more than one heat sink. In fact, it may have as many as needed or as it passes through the electrical cabinet. Thereby, the need for external heat sinks may be eliminated.

In an exemplary embodiment of the invention, said flow of air is directed to pass said middle segment by external air guides.

Such external air guide may be connected to the electric cabinet or to the electrical conductor. They may guide at least part of the air flow in a predetermined direction.

### THE DRAWINGS

For a more complete understanding of this disclosure, reference is now made to the following brief description, taken in connection with the accompanying drawings and detailed description, wherein like reference numerals represent like parts. The drawings illustrate embodiment of the invention and elements of different drawings can be combined within the scope of the invention:

FIG. 1a-c illustrates various electrical conductor according to the present invention,

FIG. 2 illustrates a flowchart according to a method of a manufacturing an electrical conductor,

FIG. 3 illustrates an electrical conductor comprising a heat sink,

FIG. 4 illustrates an electrical conductor comprising a heat sink connected to a component,

FIG. 5 illustrates an electrical cabinet comprising an electrical conductor comprising a heat sink,

FIG. 6 illustrates heat sinks at the end of an electrical conductor, and

FIGS. 7 and 8 illustrates a few embodiments where an electrical conductor has heat sinks.

### DETAILED DESCRIPTION

The present invention is described in view of exemplary embodiments only intended to illustrate the principles and implementation of the present invention. The skilled person will be able to provide several embodiments within the scope of the claims.

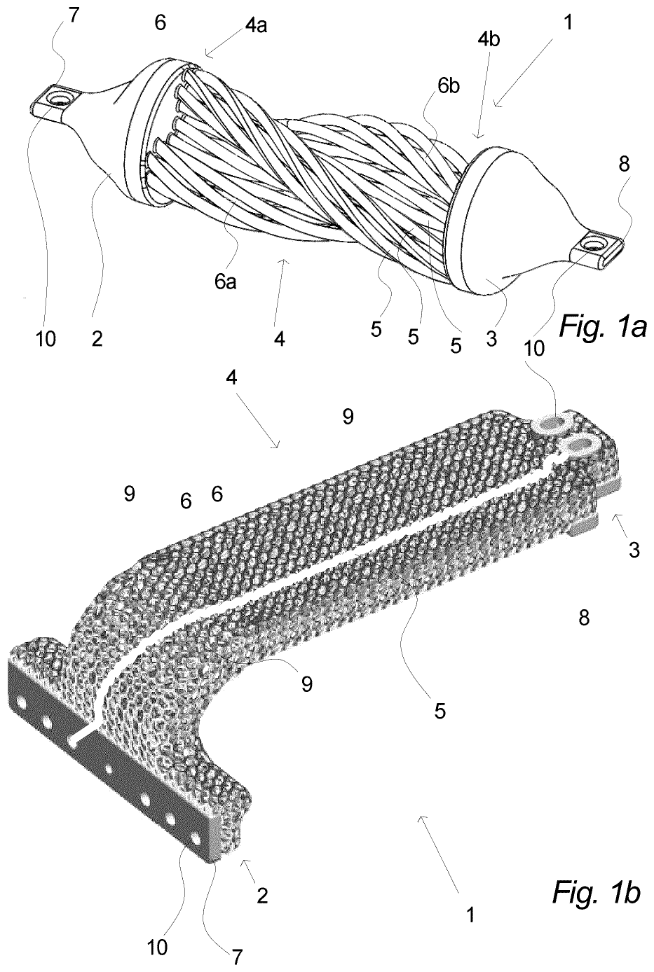

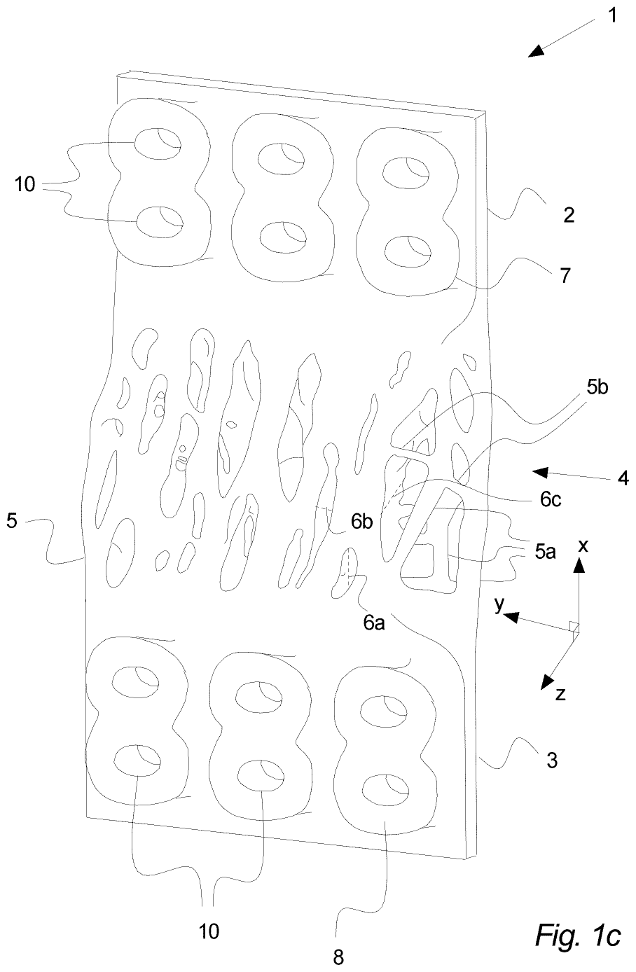

FIG. 1a-1c illustrates various embodiments of an electrical conductor 1 according to the present invention which are all suitable for comprising an intetrated heat sink. FIG. 1a illustrates an electrical conductor 1 having a twisted geometry/design. The electrical conductor 1 comprises a first end 2 and a second end 3, where the second end 3 being distal to the first end 2 and spaced apart from each other by a middle segment 4.

The middle section 4 in this particular embodiment comprises a plurality of conductor branches 5. In this particular embodiment the individual conductor branches are spaced apart by air gaps 6 both in the longitudinal and 6a transversal direction 6b of the electrical conductor 1. This twisted design of the conductor branches adds flexibility to the conductor 1 and thus the ability to absorb vibrations. Further, the design is lightweight and easy to mount.

In this particular embodiment, the first end 2 comprises a first terminal 7 and the second end 3 comprises a second terminal 8. The first and second terminals 7, 8 may comprise one or more terminal holes 10 for connecting the electrical conductor 1 to other electrical components. The electrical conductor 1 is configured to support conductance of an electric current between the first and second terminals 7, 8.

Each of these two terminals 7, 8 may, via terminal holes 10, clamps, plugs or other electrical connection means, for example be galvanically coupled to terminals, busbars, components (such as breakers, contactors, power modules, reactors, etc.) and other electrical conductors according to the present invention, etc. of an electrical installation. Typically, the electrical conductor 1 and thus the terminals, busbars, components, etc. to which it may be connected would be comprised by an electric box i.e. located inside an enclosure such as a panel, cabinet, etc.

In various embodiments, the electrical conductor 1 may have several first ends 2, several second ends 3, several first terminals 7, and/or several second terminals 8.

FIG. 1b illustrates an electrical conductor 1 having a web-like or lattice-like geometry/design. As the electrical conductor 1 illustrated in FIG. 1a, the electrical conductor illustrated in FIG. 1b comprises a first end 2 and a second end 3 separated by a middle section 4. The first end 2 may comprise a first terminal 7 and the second end 3 may comprise a second terminal 8. The first and second terminals 7, 8 may comprise one or more terminal holes 10 for connecting the electrical conductor 1 to other electrical components.

Between the two terminals 7, 8 conductor branches 5 in a web-like structure extend (only one is highlighted). These conductor branches meet and branch off in a plurality of intersection points 9. Note that the first and second ends 2, 3 are also partly manufactured as a web-like design as the middle segment 4. Also note, that the first and second terminals 7, 8 comprise more than one terminal hole 10. The terminal holes 10 of the terminals 7, 8 is made in a part of the ends 2, 3 which has non-perforated surface i.e. a surface different from the web-like surface of e.g. the middle segment 4 of the electrical conductor in this particular embodiment. The planar contact surface of the terminals 7, 8 around the terminal holes 10 is preferred to provide a connection surface to another flat surface with as little resistance as possible and sufficiently strong contact surface between bolt/nut and electrical conductor 1.

FIG. 1c illustrate an electrical conductor having a bionic geometry/design. As the electrical conductor 1 illustrated in FIG. 1a and 1b, the electrical conductor illustrated in FIG. 1c comprises a first end 2 and a second end 3 separated by a middle section 4. The first end 2 may comprise a first terminal 7 and the second end 3 may comprise a second terminal 8. The first and second terminals 7, 8 may comprise one or more terminal holes 10 for connecting the electrical conductor 1 to other electrical components.

The middle segment 4 in this embodiment is of a so-called bionic design, preferably achieved as a computer generated design. Such computer-generated design is provided based on input to a computer program controlling an additive manufacturing machine/process or able to export data to a controller of an additive manufacturing machine/process such as from a user or another computer. Input may include dimension, maximum current to be conducted, required strength, maximum deflection (elastic or plastic), etc. As the electrical conductor illustrated in FIG. 1b, the electrical conductor of this particular embodiment comprises both longitudinal conductor branches 5a and transversal conductor branches 5b. It is noted, that together the conductor branches 5a, 5b forms a transversal conductor branch outgrowth i.e. if seen in a side view, the electrical conductor 1 of FIG. 1c would be thicker at the middle section 4 than at the ends 2, 3. The conductor branches 5 are spaced apart in space by air gaps 6 in both X (6a), Y (6b) and Z (6c) directions. Further note, that the terminals 7, 8 are designed with a planar surface to obtain best possible contact with a component having a planar surface, to which the electrical conductor 1 is to be connected to, such as clamped against, via for example bolt and nuts. Also note, that independent from the geometry of the ends 2,3, the terminals 7,8 are aligned/raised so that the contact surface for, e.g., all three terminals 7 are in the same plane.

The above embodiments of an electrical conductor 1 all feature airy geometries having air gaps 5 between conductor branches 6. The electrical conductor 1 of the present invention may in other embodiments feature other airy geometries such as web-like, gyroid-like, lattice-like, etc., as described in more detail herein, which in various embodiments may provide improved cooling, reduced material consumption, improved flexibility, and/or other advantages described in more detail herein. The term ‘-like’ is used in connection with gyroid-like, lattice-like, etc., to emphasize that it is an airy geometry resembling the named structure, rather than a specific systematic structure, that is relevant in preferred embodiments of the invention.

It should be noted that the three different designs of electrical conductors of the present invention illustrated in FIG. 1a-1c is not limiting for the designs or geometries or structures that is possible to manufacture according to the present invention. Other designs that are possible to represent digitally and transfer to an additive manufacturing device and thus manufacture by additive manufacturing is considered to fall with the scope of the present invention. This includes designs having plane surfaces with internal ducts, manufactured by different materials, manufactures with protrusions or recesses, manufactured to have auxiliary functions beside conducting current, etc. Particularly, high-power conductors are advantageous to manufacture according to the present invention.

Note that embodiment of the invention, such as the above-described electrical conductors, may comprise further terminals 7, 8 between the ends 2, 3, which are not illustrated. Also note, that a plurality of the illustrated electrical conductors 1 may be connected to form a complete electrical conductor. In this case the first and second end 2, 3, is referred to as the ends of the complete electrical conductor which may comprise terminals 7,8 and e.g. terminal holes 10 for connecting the complete electrical conductor to other components. Between these first and second ends 2, 3 of the complete electrical conductor, terminals 7, 8 of a plurality of electrical conductors as illustrated may be connected.

The cross-sectional area of the conductor/conductor branches can be exploited to its full potential in an electrical conductor of the present invention. The conductor is designed and manufacture to have a cross-sectional area that is able to comply with requirements to current to be conducted without have excess of material used. The design of the present conductor may not have surplus material which is not used for conducting current when nominal current is supplied e.g. to a 1400 A power module. If extra material is used, this is used for cooling the conductor or a safety margin. The amount of such extra material can be determined relatively precise by the software which is used to design the conductor. As a rule of thumb, the larger surface for cooling, the higher amps is possible to conduct. The design software may be able to put weight on amps, cooling properties (cooling medium, surface, etc.), frequency of the current when designing the geometry of the conductor, etc. when designing the conductor. Accordingly, a conducting cross-sectional area of a conductor as illustrate in FIG. 1b may be 80 mm2 may in certain embodiments be sufficient to conduct a current of 1300 A due to the airy design allowing a very advantageous cooling. In fact, tests have shown that the temperature of a conventional massive busbar with a conducting cross-sectional area of 516 mm2 conducting 1300 A increases to a temperature where neighboring components of plastic is in risk of melting.

Hence, it should be noted that the conductor may be designed and subsequently manufactured so that a percentage of the cross-sectional area of the electrical conductor e.g., above 80% such as between 90% and 100% is used to conduct current during normal operation. This is in contrary to known massive busbars that does not exploit the material in its center to conductor current. This is at least true for most frequencies of currents conducted in high-power systems including renewable systems, vehicles and the like.

The high percentage of utilization of cross-sectional area for conducting current compared to known massive conductors is possible to obtain in that the conductor of the present invention and thus the individual conductor branches because they are designed with a cross-sectional area that sums up to be able to conduct a current of a given frequency. Further, the material reduction is also made possible because of the possibility of cooling also inside the conductor. In fact, a conductor branch may along most of its length, in some embodiments along all of its length, be cooled from all angles i.e. a 360° cooling of the conductor branches is possible.

As mentioned, a conductor of the present invention may form an airy geometry which depending on the kind of airiness may not facilitate a secure or robust platform or structure for fastening the conductor e.g. to the electric cabinet. Accordingly, in proximity of through-holes for fastening the conductor or through-holes, e.g. terminal holes, for connecting the conductor to components or other conductors, the geometry of the conductor may not be airy. Preferably, around a through-hole the density of the conductor is higher or more concentrated to form an, e.g., planar surface and thereby provide the best possible preconditions for conducting current between two parts of a joint and to distribute the force required to fastening a conductor in the joint or to a support structure. Hence, a through-hole may be designed as a cylinder through which a bolt may pass through and with planar upper and lower parts extending from the periphery of the cylinder to facilitate the force and/or current distribution in the joint. Other mounting and/or terminal points may be preferred in some embodiments, such as flanges, protrusions, plugs or sockets, etc., with or without through-holes, but with the same consideration of ensuring sufficient robustness and stability of the electrical conductor for the intended mounting or connection method. The through-holes could be 6 mm, 8 mm, 10 mm or 12 mm in diameter.

It should be mentioned that terminals for electrical connection may be positioned at or between the ends of an electrical conductor. Thus, in principle, a conductor may be manufactured by an additive manufacturing process and when the first end and first part of the middle segment is manufactured these may be rolled onto a conductor holder as the middle segment is continued to be manufactured. Alternative, the conductor is guided out of the printing areas e.g. by a conveyer belt as the conductor is manufactured. This may result in a long conductor with two ends. Either during manufacturing or after, terminals may be made in the conductor and also after manufacturing, the conductor may be cut into desired lengths. In this way, terminals may be manufactured or provided either at the ends or between the ends of the conductor.

The term monolithic is in this description used to describe the geometry or structure of an electrical conductor according to the present invention. Such conductor is preferably manufactured by an additive manufacturing process and thereby, it is manufactured as a single piece, unit or block from one end to the other or at least one end and a middle segment is manufacture as a single piece. Such conductor may thus be formed from a single material as a single piece, unit or block where its one or more ends are monolithically formed with a middle segment connecting the one or more ends i.e. monolithically formed should be understood as made in one continuous process with no need for additionally adding one part to another I.e. one or more ends are manufactured together with the middle segment as one unit with no connections such as welding, soldering, or by any clamping or fastening means, except for the type of micro binding intrinsic to the particular additive manufacturing technology utilized, such as, e.g., layer-by-layer melting, sintering, liquid binding, spraying, etc. With this said, it should be mentioned, that it is possible to add additional elements such as terminals, cooling fins, etc in a post manufacturing process e.g., by a cold spray process.

Put in another way a conductor of the present invention is the result of a process forming the conductor in one structure, a conductor composed of an electrically conductive material without joints or seams and thus constituting a conductor as a rigid whole exhibiting a rigidly fixed uniformity. To such conductor it is possible to connect additional conductors via terminals and thereby branch off one current path to two or more current paths or vice versa.

It should be mentioned that the conductor may be manufactured from more than one type of material. In this situation, the conductor could be said to be polylithic. The term polylithic should in this context be understood as a geometry or structure of an electrical conductor that is manufactured in one piece as a monolithic structure, as described above, where the conductor is manufactured from two or more materials. Hence, a polylithic conductor of the present invention is a conductor resulting from a process forming the conductor in one structure where the process is using two or more different materials. Such two or more materials may be a combination of electrical conductive or non-conductive materials.

In most embodiments, the electrical conductor 1 is designed to comply with high voltages i.e. voltages above 24V such as 110V, 230V, 400V, 690V, 1000V, 1500V and up to kV systems. just to mention a few voltage levels of an electrical installation in which the electrical conductor 1 of the present invention would be suitable. In terms of current, an electrical conductor 1 according to the present invention may be designed to conduct several hundreds of amps (16, 32, 64, and so on up to 100, 200 and so on up to e.g. 900 A) up to a couple of thousand amps (1000 A-3000 A). Electrical conductors may be designed to conduct higher currents than 3000 A e.g. by improving cooling of the conductor in combination with an increased cross-sectional area of the conducting part of the conductor.

Mentioning these voltages, it should be noted, that in principle there are no lower limits as to the voltage and current. I.e., versions of the electrical conductor may be designed to be used in, e.g., 3.3V, 5V, 9V, 12V, 15V, 20V, 24V or 48V systems, such as USB power delivery PD systems, conducting currents below, e.g., 10 A, such as 5 A, 3 A, 2.4 A, or 2 A just to mention a few examples.

Thus, the electrical conductor 1 of the present invention is suitable for use in almost any type of electrical installation. This includes everything from low voltage to high voltage AC and or DC systems where transfer/conducting of current or communication signals is needed.

The present invention is particularly advantageous for electrical busbars designed for high-power electrical systems, e.g. from 10 kW and up, such as 22 kW, 50 kW, 110KW, 150KW, 225KW, 300 kW, 350 kW, 500 kW,800 kW,1 MW,2 MW, 3 MW, or even higher, such as e.g. 5 MW or 10 MW systems, with voltages of e.g. 110V, 230V, 400V, 690V, 800V, 1000V, 1500V, 6kV or e.g. 10kV, and currents from e.g. 16 A, 32 A or 64 A, to several hundreds, e.g. 100 A, 200 A or 500 A, or even thousands, e.g. 1000 A to 4000 A. By local connecting busbar is referred to busbars for local connections inside such a high-power electrical system, e.g. contained inside an electrical cabinet housing a power converter, inverter, transformer, generator, electric motor, breaker, high-power battery system, battery charger, or similar power systems, possibly including capacitors, reactors or inductors, power resistors, dump loads, etc. A system, component or conductor may be categorized as a high-power system, component or conductor if it is operating at currents in the range of 800-1000 A or higher.

Non-limiting examples of such electrical installations/systems include energy facilities such as grid components such as substations with grid support, voltage regulation, power to x plants, etc., energy generating systems such as wind turbines, wind farms, solar plants, etc., electric installations in a private homes and industry, industrial machines, household appliances, etc. and means for transportation such as airplanes, heavy duty vehicles, light duty vehicles such as automobiles, trains, ships, etc.

Accordingly, the electrical conductor may be a high-power electric conductor of a high-power electric system. In a high-power electric system, conductors may be spaced apart and/or isolated from each other with greater distances than what is possible e.g. in an electrical motor. This distance is referred to as a safety clearance and the size of it depends on the voltage differences in the system. Thus, when depending on air as isolator between an otherwise non-isolated busbar/conductor and another conductor or structure of conductive material such as a metal cabinet, the distances must be taken into account in compliance with safety regulations. It should be mentioned that air quality/pollution degree, such as humidity and particle content, may also be relevant for the distance of the safety clearance. In case a conductor is used in a high-voltage system the surface is manufactured to reduce field concentrations.

Further, the cross-sectional area of a current path through a conductor according to the present invention is larger than the cross-sectional area of e.g. a winding of an electric motor. This may be true both with respect to a cross-sectional area at a given point of the conductor and over a distance of e.g. 20 cm or 30 cm in the longitudinal direction of the conductor and physical dimensions.

Current conducting busbars of a high-power installation or system is typically fastened to a structure comprising the system for every 25-35 cm. If the current is conducted by cables, the distance between cable fasteners may be even smaller. The fastening may be made by screwing bolts into a support structure such as an electric cabinet or by screwing clamps to the support structure which is then closed and thereby fastening the cable/busbar. The conducting cables/busbars are of course insulated from the support structure.

In such high-power installations where the primary aim of conductors is to distribute electric energy to components, the magnetic field around a conductor of the present invention is not as important as it is e.g. around a winding of an electrical motor. Thus, since the magnetic field is not the main purpose for manufacturing the electrical conductor for a high-power installation the conductor is typically not designed to have a certain magnetic field when conducting current.

Further, again comparing to e.g. a winding of an electrical motor, a conductor of the present invention would as a general rule be designed with a surface area that is as large as possible to optimize the possible advantages of the invention as described herein. Depending on the purpose of the conductor, the surface may for example be designed for conducting current, conducting current and heat dissipation or heat dissipation. Thus, even though all portions of a conductor of the invention may comprise an electric conductive material, not all portions are necessarily used for conducting current through the conductor. In general, the available area around a conductor is exploited to expand the surface of the conductor for one of, for example, the heat dissipation or current conducting purposes, or other described purposes such as improved flexibility, reduced material consumption, air guidance, etc. The available area is limited by safety clearances to other conductors of different phases having different voltage levels, grounded structures such as elements of an electric cabinet, etc.

An example of a portion of a conductor that is primarily used for non-conducting purposes such as heat dissipation or air guidance, is an outgrowth from the surface of the conductor which is not connected at the distal end of where it is growing from the surface of the conductor. Such outgrowth or protrusion may for heat dissipation purposes preferably comprise some kind of bionic design with airgaps between branches, possibly with a continuous surface towards a direction of air flow for air guidance purposes. Such portions would be referred to as conductor branches if these were part of the middle segment conducting current form one end to the other. Such outgrowth may in principle take any form or geometry exploiting the free space around the area as long as safety clearance distances are maintained. In such examples, the fraction of current conducted by the surface area of the outgrowing conductor portion is very small if not zero.

An example of a portion of a conductor that is only used for conducting a current may in principle not be possible in that heat dissipates even from a solid block and a planar surface. What should be understood by a portion of a conductor primarily used for conducting current, is a varying structure or geometry for a middle segment of the conductor between the first and second terminals. When space is narrowed between components in an electrical system, if other conductors are to be passed, if the conductor has to pass through a current sensor or bushing, etc., the surface area of that particular portion of a conductor middle segment may be reduced to comply with available space, thereby typically increasing the conductor density to achieve a narrower outer dimension. In this example, at this particular portion of the conductor, the current conducting portion of the surface area of the conductor becomes high; possibly so high that a hot spot is created where additional cooling is required to continue to maintain a certain current conduction capacity. Hence, this is an example which may benefit from a combination of the conducting portion with an outgrowth portion, as described above, e.g. on each side of the narrowed part of the conductor. In this way, heat generated at the narrow space can be dissipated via the nearby outgrowths, e.g. further in combination with internal cooling channels.

An example of a portion of a conductor that is used for both heat dissipation and current conduction is a middle part between the terminals, with an airy design or geometry. In such example, the surface areas having the main purpose of dissipating heat and conducting current, respectively, may be the same or close to be the same. This is due to a geometry comprising conductor branches spaced apart from each other so that a flow of cooling air may pass freely by each conductor branch, i.e., through air gaps defined by the conductor branches. In this example the current conducting surface area is large compared to traditional conductors/busbars and windings e.g. of an electric motor. Another difference between a motor winding and a conductor of the present may be found in the circumference of the conductor. The limited space inside a motor obviously limits the circumference of the winding. This is not the case to the same extent e.g. in an electrical cabinet comprising a conductor of the present invention. More space is available and thus the circumference can be made larger leading to an airy design with airgaps for increased cooling. Further, the cross-sectional area of the individual conductor branches of a conductor according to the present invention is often lower than the cross-sectional area of a motor winding.

As mentioned, the electrical conductor 1 may comprise first and second ends 2, 3 spaced apart by a middle segment 4. One complete or final electrical conductor may comprise a plurality of interconnected electrical conductors 1 of the types illustrated/described above. In such embodiment the illustrated electrical conductors may be used as sections of the final or complete electrical conductor. Thus, a final or complete electrical conductor may comprise first and second ends 2, 3, with a plurality of first and second terminals 7, 8 at the ends or between them, e.g. with terminal holes 10 for connecting a plurality of the illustrated/described electrical conductors to form the final or complete electrical conductor.

The terminals 7, 8 may comprise one or more terminal holes 10 or other structures for connecting the electrical conductor 1 to other electrical conductors such as busbars, cables or the above-described electrical conductors, electrical components such as breakers, power modules, batteries, etc.

Alternatively, in an embodiment, one or both of the terminals 7, 8 of the electrical conductor 1 form part of an electrical component as an alternative to being provided as freely connectable locations at the conductor 1.

A terminal 7, 8 may in a simple embodiment comprise a terminal hole 10 through the terminal 7, 8. Via such hole, a bolt can go through and continue through a component with which the electrical conductor 1 is to be connected. The electrical conductor and the component are then clamped together via a nut and the bolt.

Alternatively, a terminal 7, 8 may be a click terminal that is either designed to receive a click part form a component to which the electrical conductor is the be connected or designed with a click part that is to be inserted into such other components.

Alternatively, a terminal 7, 8 at an end 2, 3 of the electrical conductor may be manufactured with a threat which when engaging with a bolt is able to assist in clamping a component to the electrical conductor 1.

Further, it should be noted, that an electrical conductor as illustrated or a complete electrical conductor comprising a plurality of electrical conductors such as the above described may have more than one first end 2 or more than one second end 3. Hence, one end of an electrical conductor 1 may branch off in e.g. three terminals each with a terminal hole. This may be advantageous in that the geometry of the electrical conductor is then designed specifically to the component to which it is to be connected. Branching off the ends into several terminals may also improve heat dissipation capacity at the possibly denser terminal portions, improve electrical connection between the conductor and components, and avoid additional connection pieces or shunts in order to connect adjacent components to a common conductor.

The middle segment 4 may comprise one, but preferably a plurality of conductor branches 5. The conductor branches 5, like the end segments 2, 3, are at least partly made of an electric conductive material such as copper or aluminium or alloys thereof, enabling the electrical conductor 1 to conduct a current between its terminals 7, 8. The design of the conductor branch(es) 5 may be optimized according to a specific purpose such as cooling, material consumption, flexibility (control in a particular direction), footprint, etc. Thus, depending on which parameter(s) the electrical conductor 1 is designed according to, the conductor branches may be designed as longitudinal cylinders (or other geometries such as oval, square, etc.), web, bionic, gyroid-like design, lattice-like design, branch-like design, or sponge-like design, coil or solenoidal designs, spirals, etc.

Thus, the electrical conductor may have a perforated surface, a non-perforated surface, a massive structure or a structure with internal channels optimizing the electrical conductor according to skin-effect and cooling, etc.

Two or more conductor branches 5 may meet in an intersection point 9 and two or more conductor branches 5 may branch off from an intersection point 9. This has the effect, that an electrical conductor is established that maintain a desired strength (determined yield point) with a minimum of material. Among others, this may reduce the cost of the electrically conductive material and reduce the weight of the conductor. It should be mentioned that two conductor branches meeting in the intersection point 9 may be the same two conductor branches leaving that intersection point 9. Alternatively, two other conductor branches may leave the intersection point, however this may be a question of definition of a conductor branch. Further one conductor branch may branch off to a plurality of conductor branches and a plurality of conductor branches may meet and form a lower number of conductor branches.

Further, it should be mentioned that the electrical conductor 1 may be designed as a plurality of electrical conductors, e.g. as a combination of three phase conductors or as a wire harness or printed circuit board traces of a printed circuit board used for mounting in an electric panel.

At least a first end 2 and a middle segment 4, but preferably also the second end 3, of the electrical conductor 1 of the present invention are monolithically formed, since they are manufacturing from a single bulk of material, which is machined to provide the electrical conductor 1. Here bulk of material should be understood as the material such as electrically conductive material of which the electrical conductor 1 is made, e.g. a solid, powder, liquid, wire, etc. Here machined should be understood as manufactured by additive manufacturing, i.e. the electrical conductor 1 is made in one piece without any mechanical connections of the first end 2, second end 3 and middle segment 4.

Note that more than one type of material, e.g. two bulks of material, may be used to manufacture the electrical conductor. One of such two or more bulks of material may be electrically non-conductive.

Note that in some embodiments it may be necessary to manufacture the electrical conductor in more than one piece. In this situation the electrical conductor may be referred to as a complete or final electrical conductor which comprises a plurality of electrical conductors 1 as described above. This may be the case e.g. if the electrical conductor needs to be mounted in a location where it cannot be inserted unless the electrical conductor is separated in two or more pieces or if the complete electrical conductor has to be larger than what is possible to manufacture by additive manufacturing. In such situation, terminals of two electrical conductors are connected, extending the length of the middle section and thereby the current path between the first end 2 and the second end 3 and thus of the complete electrical conductor. Such connection may be prepared by designing terminal holes in the conductor where, e.g., fish plates or other joints may be fastened and thereby connecting the two middle segments.

It should be noted that the electrical conductor 1 may have a non-uniform geometry/design. The design/geometry may take any machinable/printable shape. Such shape may be optimized according to conducting current (skin effect), cooling, guidance of flow of cooling fluid, other components in a panel, resistance, power loss or current displacements, etc.

In a particular embodiment, the electrical conductor 1 may have a non-uniform diameter (measured in a transversal direction) along the lengthwise direction. A well-defined diameter may nevertheless be determined e.g. at a transversal plane at which that electrical conductor 1 has its smallest diameter.

Moreover, in an embodiment of the invention the perimeter length of the electrical conductor 1 or its conductor branch(es) 5 may vary in transversal planes at different positions in the lengthwise direction of the electrical conductor 1. The perimeter length of a given part of the middle segment may simply be measured as the sum of all lengths of perimeters of branches in a given transversal plane. Hence, the perimeter length at a given part may thus be the length of the perimeter of conductor branches measured across/perpendicular to the longitudinal direction of the electrical conductor at that part. A part of a conductor may also be referred to as a portion of a conductor and should be understood as a reference to a specific portion of the conductor such as an end or middle segment.

The perimeter length of the conductor branches 5 may be the sum of lengths of perimeters of all individual conductor branches 5. As one conductor branch may split from a stem to two or more twigs, i.e. branches of a branch, the perimeter at one part of the conductor branch may be different from one part (e.g. a twig part) to another part (e.g. a stem part). Hence, the sum of lengths of perimeters of the conductor branches may be the sum of all individual twigs or of all the individual stems. In case of multiple different possible perimeter lengths for the conductor parts along the length of the electrical conductor, the smallest perimeter length may preferably be used in calculation of current conduction capability of the electrical conductor 1.

In the same way, the cross-sectional area of an electrical conductor at a given part is measured as the sum of the cross-sectional area of all conductor branches at a given part along the length of the electrical conductor. The cross-sections at that part should be measured perpendicular to the longitudinal direction of the electrical conductor.

In an embodiment, the electrical conductor 1 may comprise one or more cooling channels, where the cooling channel may be placed inside the one or more conductor branches, transversally and/or longitudinally.

The manufacturing of the electrical conductor 1 may be done by an additive manufacturing process. Such manufacturing process may be based on, but not limited to, one of the following additive manufacturing processes: 3D printing, layer by layer printing, Wire Arc Additive Manufacturing, Fused Deposition Modeling FDM, Direct Energy Deposition, Direct Metal Deposition, sintering based processes, laser based processes, for example Powder Bed Fusion PBF, such as selective laser melting SLM or selective laser sintering SLS, cold spray additive manufacturing CSAM, binder jetting or binder jet 3D printing, etc. It should be mentioned that the actual additive manufacturing process used to print or build the electrical conductor 1 may not be important as long as the material of which the electrical conductor is built is an electrically conductive material.

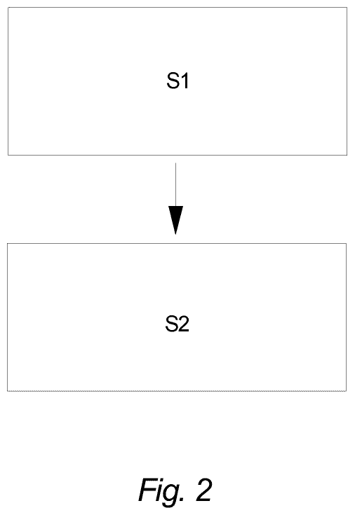

FIG. 2 illustrates method steps for machining an electrical conductor 1 according to an embodiment of the invention. The particular method relates to forming an electrical conductor with two ends or two terminals, namely a first end/terminal and a second end/terminal via a middle segment, but may be used for producing any kind of electrical conductor of the present invention.

It should be mentioned that this may include manufacturing both ends and the middle segment in one process. Hence, with additive manufacturing along the longitudinal direction of the conductor, the method may start by manufacturing, such as printing, one end, then a transition to the middle segment, possibly one or more conductor branches, then the middle segment, then a transition to the second end and finally the second end. In another embodiment, the additive manufacturing occurs transversal to the conductor's longitudinal direction, thereby for example manufacturing portions of both ends and the middle segment simultaneously, increasing the cross section with each applied layer. In another embodiment, the additive manufacturing is radial, or even arbitrary, to the conductor's longitudinal direction, for example using cold spraying CSAM or Fused Deposition Modeling FDM while rotating or freely moving either the conductor unit being built or the nozzle, or both. Preferably, the mentioned segments are manufactured in one process, e.g. as one segment is manufactured, the next segment is being manufactured. A transition part may be made between such two segments which may start or include the first segment. Similarly, the second segment may include a transition part or is connected to such transition part.

It should also be mentioned that the method could in some embodiments comprise manufacturing the middle segment and afterwards connect the end segments. The end segments could be connected while being additive manufactured or could be connected with an additive manufacturing thermal paste or glue after being made. The end segments could also be welded, glued or connected in any other way to the middle segment, e.g. by cold spraying CSAM.

An additional embodiment of the invention could be a manufacturing method that comprises two or more middle segments being additive manufactured. The two or more middle segments could be additive manufactured in the same process with the two end segments to form the electrical conductor. The two or more middle segments could also be additive manufactured separately and connected afterwards to form the electrical conductor.

The two or more middle segments could be identical or could be two differently shaped or otherwise characterized middle segments depending on where the electrical conductor should be placed in e.g., an electrical cabinet.

A transition may straightforwardly be defined as a change of size of a layer compared to a previous layer. In this way a transition may be formed as a perpendicular transition between an end segment and a conductor branch of the middle segment. Alternative, subsequent layers may change in cross-sectional area and thus form a transition as a rounded transition which may be advantageous in terms of a reduced resistance for current conducted between the ends of the electrical conductor.

A monolithic conductor according to the present invention is made from one material. One or more additional materials may be used e.g. as isolation, for heat dissipation, etc. in this case the conductor may be referred to as a polylithic conductor. No matter the number of materials, a conductor produced by additive manufacturing is produced bit-by-bit starting at a first spatial coordinate (x, y, z) and ending at a second spatial coordinate. At least when the conductor is finished the first and second spatial coordinates are electrically/mechanically connected. As mentioned several methods of manufacturing a conductor exists all including some kind of material depositing, joining or soldering to manufacture a conductor in one monolithic form.

In this document a conductor may be referred to as being manufactured layer-by-layer no matter the additive manufacturing method used. Hence, if a conductor is sliced (no matter in which orientation) and one is looking at the cross-section of the conductor it is easy to imagen that the conductor is manufactured starting with material in first point, then with material in a second point and so on. Since the conductor is volumetric i.e. has a three dimensional geometry the first point is different from the second and subsequent points at least in one of the spatial X, Y and Z directions/plans. Thus, with reference to the spatial X, Y and Z planes a conductor could be said to be built from a plurality of subsequent layers even though when manufactured all material in one plane such as X=1 and Y=0 and Z=0 is not provided as a one layer or in one layer before material in a next layer (e.g. an X=2 layer) is provided.

Hence, no matter which of the processes of manufacturing a three-dimensional object such as a conductor that is used, it can be said that the conductor is manufactured layer-by-layer even though some of these manufacturing processes are based on deposited, joined or solidified with material being added together in areas, lines, pointwise, etc. This is because no matter the additive manufacturing process the conductor is manufactured one point after the other. A plurality of points in the same plan (e.g. X=3) is considered one layer also if they are not physically connected in this plane. And when all points of this layer are added, points of the next layer (e.g. X=4) is added to the points in the X=3 layer. As mentioned, a layer may be defined in any of the planes of a spatial Cartesian coordinate system.

Alternatively, the ends may be separate segments that are connected via the middle segment. The middle segment may be printed, and during the manufacturing of the middle segment it may be attached to the ends such as printed, heated, glued or the like onto the ends. The middle segment may be joined to the ends by means of welding, printing, soldering, etc.

It should be noted that the ends may comprise terminals for connecting the electrical conductor to other electric parts/conductors/windings of an electric system. Such terminals may be manufactured like the rest of the electrical conductor by additive manufacturing i.e. monolithically formed with the ends.

In a step S1 of this particular method, considering additively manufacturing a conductor in its longitudinal direction from the first end towards the second end, the first end segment and middle segment in the form of conductor branches of a plurality of conductor branches are monolithically formed via individual transitions that may or may not include rounded connections to shape concavely rounded interior corners between the first end segment and conductor branches of the plurality of conductor branches and to spatially separate conductor branches of said plurality of conductor branches.

The step of monolithically forming the first end segment and conductor branches may be implemented using various methods, for example methods such as additive manufacturing such as 3D printing, casting, and simply removing of material, via machining, from a bulk metal slab to form conductor branches combined with a first end segment.

More specific, a known massive conductor such as a main busbar with a length of e.g. 3-5 m may conduct 1-2 A per mm2. If the same busbar was made in an airy design and e.g. with an internal cooling, then due to the improved cooling the same 1-2 A per mm2 may be conducted with the same efficiency despite the removal of material. Typical conductor materials such as aluminium and copper have temperature coefficients at approximately 0.4%/deg C. If such conductor is efficiently cooled so that the temperature is e.g. 25 deg C. lower compared to a conventional conductor, the resistance is reduced by approximately 10%. Hence approximately 10% of the material can be removed without compromising the losses. Furthermore, in AC conductors the current is not evenly distributed across the conductor volume. Typically, the current density is reduced towards the center of the conductor. Taking such considerations into account can allow for further removal of material without compromising the efficiency of the conductor.

In a step S2 of the method, the first end segment becomes electrically coupled and mechanically coupled to a second end segment via the middle segment of the electrical conductor formed by the plurality of conductor branches. This may also be monolithically achieved, e.g. by continuing the additive manufacturing, as described in step S1.

The coupling of the end segments to the middle segment could also be done by welding, gluing, male/female locking mechanism or any other way that would connect the segments both mechanically and electrically.

An optional, additional step of the method of manufacturing the conductor of the invention comprises a step prior to the step of additive manufacturing any of the first, second or middle segments. The step prior to manufacturing the electrical conductor is a step where a digital representation of the electrical conductor is designed in a software program, e.g. a 3D CAD software. The step of designing the digital representation of electrical conductor in a software program includes taking the electrical, mechanical, structural, geometry and other aspects of the physical electrical conductor into account. Thus, based on these inputs, e.g. provided by a user of the 3D CAD software, a digital representation of the conductor is provided by the 3D CAD software. When the digital representation of the electrical conductor is complete the additive manufacturing process can be started.

A further optional step may be applied i.e. a heat treatment to the finalized conductor. A heat treatment may e.g. be 4 hours at 400 C and upwards depending on the material. An advantage of heat treatment is that the particles of the manufactured conductor is mutual positioning or merging leading to higher conductivity both thermal and electrical. This is at least true for Aheadd® CP1 20/63 aluminium powders and other aluminium-iron-zirconium powder solutions. Such powders may be used in laser powder bed fusion machineries. Using this type of powder and heat treatment may lead to higher thermal stability, thermal conductivity, corrosion performance and surface finishing as well as higher electrical conductivity.

The middle segment may in principle have any design/geometry, for example providing flexibility thereto allowing the electrical conductor to deform. It may be formed by conductor branches being solid or having internal cavities to reduce the amount of material that is needed to manufacture the electrical conductor. It may be formed by a web or as a hybrid between conductor branches or web just to mention a few possible designs.

Internal cavities may be used as cooling channels and/or additional surface for conducting high frequency current. Accordingly, the end segments and middle segments may be designed for the particular panel/electric system in which it is used, for a particular type of current to conduct, for having a desired or dual functionality, etc.

One such functionality, beside the above-mentioned may be as a structural support. Hence, if needed the electrical conductor may be designed to assist in carrying the weight of electric components connected thereto. Hence, its dimensions may be larger than what is needed by it for carrying the required current. Similarly, its geometry may be designed for the combined purpose of mechanical support and electric conductance. This is especially true if such support is flexible/deformable in that it may both assist in supporting and at the same time assist in absorbing vibrations.

It should be mentioned that the electrical conductor 1 may be manufactured in two or more resolutions. The thicker layer the faster manufacturing. The layer thickness depends on the material and printing apparatus and may vary from a few millimetres to 20 um, using some combinations the layer thickness is between 50 um and 150 um. In case of additive manufacturing resolution may be defined by thickness of the layers of which the electrical conductor is built (another word for machined and processed). A first resolution that is finer i.e. having thinner layer size than a second resolution may be used when manufacturing the interface between the electrical conductor and the part to which it is connected. Such interface may be the part of the terminal that is in contact with the other part. Alternatively, resolution may be determined by material deposition rate, material flow rate, etc. depending on the type of additive manufacturing used.

To avoid electric losses in connections between two electrical conductors it is preferred that the two parts have mating surfaces, which is most simply achieved by having planar surfaces, but may also be achieved by convex and concave combinations, mortise or finger joints, engaging teeth, cylinder and peg, tongue and groove, slide lock, etc., to further achieve additional advantages, e.g. larger surface area of connection, easier assembly of electrical conductors such as busbars in electrical systems by self-locking, etc., as long as good electrical connection is prioritized. The finer these interfaces are manufactured the better/the less post manufacturing processing is needed to ensure sufficiently mating surfaces, such as planar surfaces.

The second resolution manufactured e.g. with thicker layers would be more rough leading to more surface area. At least for middle and high frequency currents this may lead to conductance of more current without increasing the need for material/dimensions of the conductor. In fact, the middle segment may be manufactured intentionally with a corrugated surface to increase the current-carrying outer surface of the electrical conductor (current-carrying with medium and high frequencies) because of more efficient cooling due to the turbulence of, e.g., cooling air flow created due to the corrugated surface. It should be noted, that if the conductor includes an interior space, the inner surface of the conductors creating such interior space may also be corrugated for the same purpose. A corrugated surface has the effect, apart from offering a larger surface area, that it introduces turbulence in the flow of cooling fluid such as air. Increased speed of cooling fluid may lead to higher cooling effect.

As an example, the depth into the conductor which is used for conducting current at medium and high frequencies may in a specific embodiment be approximate 1.5 mm. In this specific example, the conductor is made of copper with a resistivity of approximate 1.68 μΩ cm, a relative permeability of approximate 1 at a frequency of 2 kHz. Thus, a conductor for this particular embodiment may be hollow having conductor thickness of 2 times 1.5 mm. In practice such conductor may be manufactured with a thickness of 4-5mm leaving room for a cooling in the interior or simple reduction of conductor material and thereby weight.

Knowing that skin effect also appears at e.g. 50 Hz, a reference to a medium frequency with respect to skin effect is a reference to frequency starting around 500 Hz where the design of the conductor may account for the skin effect. The medium frequency range may be between 500 Hz and 10 kHz, above 10 kHz may be referred to as high frequency where skin effect is a fact (the higher frequency, the closer to the surface the current will be conducted).

Further, it should be mentioned that the outer surface may also be corrugated or designed with fins for increasing heat dissipation from the electrical conductor.

The electrical conductor resulting from the method may be used as an electrical conductor of an electrical installation. The electrical installation may be an electric panel which may be part of a renewable energy facility such as a wind turbine, solar system, grid, substation, etc. The electrical installation or system in which the electrical conductor is used may be an electric vehicle, battery system, power to x facility, ship or other minor or larger electric systems. Further, an electrical conductor resulting from the method can be used inside an electric panel, i.e. in a cabinet/enclosure, or outside such panel, it can be used to connect separated panels, etc.

A variant of an electrical conductor according to the present invention is connected to a traditional cable or busbar. In such embodiment, a traditional busbar e.g. in the back of an electric panel or a traditional cable e.g. between two electric panels may be connected to an electrical conductor of the invention. In this way a traditional cable or busbar may be connected to a component via a conductor according to the invention. Thereby, an easy connection is facilitated due to the flexibility of the electrical conductor of the invention.

However, note that manufacturing the electrical conductor, and thus accomplishing the electrical and mechanical coupling between the first end segment and the second end segment, is typically performed prior to installing the electrical conductor in the electrical installation, and prior to installing the electrical installation in the renewable energy facility. Thus, according to typical embodiments of the invention, the electrical and mechanical coupling is performed prior to installation/integration of the electrical conductor. Nevertheless, methods according to the invention are not necessarily restricted to a particular sequence of steps. Further, various methods according to the invention may comprise additional steps, such as performing digital geometry optimization, additively manufacturing the electrical conductor, and conducting current.

Summing up, a designer is designing a digital representation of the conductor according to electrical, mechanical, structural, etc. requirements in e.g. a 3D CAD software such as Solidworks. Files (digital representation) from such 3D developing tool is exported to e.g. a 3D printer, where the conductor is printed according to the CAD files.

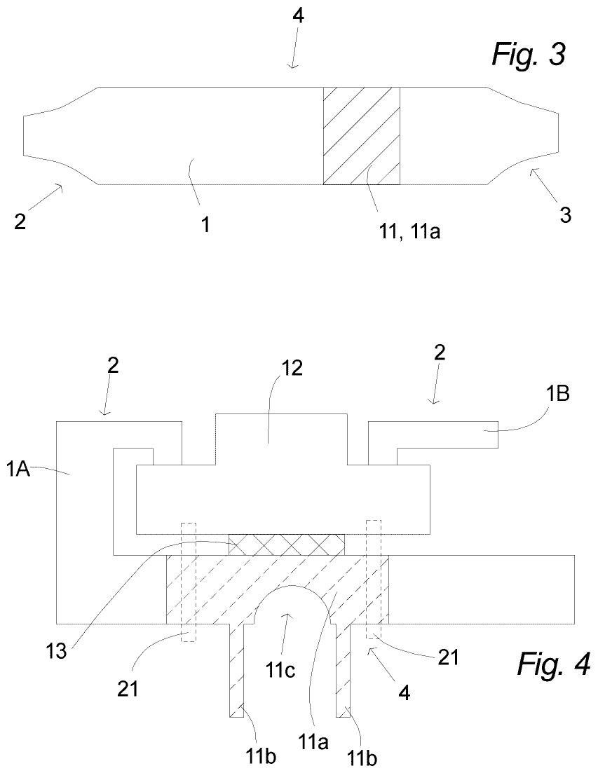

As mentioned above, FIG. 1a-1c illustrate various embodiments of an electrical conductor 1 which may comprise one or more heat sinks 11 according to the present invention. The electrical conductor 1 illustrated on FIG. 3 is seen in a top view and has two ends 2, 3 and a middle segment 4. At least the middle segment 4 of this conductor 1 comprises a heat sink 11 formed as an air penetrating heat sink 11b.

The remaining part of the conductor/conductor surface may have the same geometry as the heat sink 11 and thus in practise the entire conductor 1 may work as a heat sink. However, in the embodiment illustrated in FIG. 3, only part of the middle segment 4 comprises the heat sink defining design.

An air penetrating heat sink 11b should be understood as a structure of the current conducting middle segment 4 that allows a flow of air to travel through while current is conducted through this structure. Hence, an air penetrating structure comprises a plurality of air gaps 6 that may be uniform as in a web structure (see FIG. 1b) or different as in a bionic design (see FIG. 1c).

Note that the conducting cross-sectional area of the conductor 1 should be maintained the same or at least above a minimum cross-sectional area both where no heat sink is implemented and where a heat sink is implemented. Hence, when manufacturing the conductor 1 with integrated heat sink 11, the airgaps 6 establishing the air penetrating design are compensated for e.g. by letting the physical size of the conductor grow to maintain a desired minimum cross-sectional area.

FIG. 4 illustrates a component 12 connected to a conductor 1. The component 12 is a heat generating component which when operating is generating heat which has to be removed from the component in order to ensure continuous operation at nominal load, reach expected lifetime and in general comply with requirements to operation condition from the component manufacture. In order to obtain a compact design of the high-power electrical system in which the component 12 is used, a conductor 1 with an integrated heat sink 11 is electrically connected to the component e.g. as a power supply/power conductor for the component 12. The electrical connection is at the terminals of the components. Further, the conductor 1 is also thermically connected to the component 12 at a location that is different from the location of the electrical connection between the conductor 1 and the component 12.

As illustrated, the component 12 is connected to a first conductor la comprising the heat sink 11 and a second conductor which does not comprise a heat sink. It should be noted that a conductor with a heat sink that is not connected electrically to the component may also be used for removal of heat from the component via an integrated heat sink that is thermally connected to the component. In any case requirements to distances and isolation have to be complied with.

The conductor 1 is illustrated as carrying the component 12 or at least connected to the component 12 e.g. via fasteners 21 such as screws or bolts. Such fixation of a component 12 in/to the conductor alone 1 may be possible, however typically, the component 12 is also fixed or supported by a DIN rail or other support structure and thus typically supported indirectly by the electrical cabinet in which the component 12 and conductor 1 is enclosed.

The illustrated heat sink 11 comprise various different elements such as an air penetrating geometry 11a as a base, from this base protrusions 11b (which also may be air penetrating) are formed and finally a recess 11c is formed in the base. It should be mentioned that the heat sink is designed by a computer software based on input from a user e.g. relate to available space for geometry of the heat sink, current levels, operation time, etc.

The recess 11b may be used to establish a predetermined air flow into the base part 1 la and protrusions 11b. It should be noted that not illustrated air guides may also be used to guide air flow in a particular direction. Further the protrusions 11b may have a dual function of guiding air flow and transporting heat away from the component.

The heat sink 11 is either monolithically formed with one of the ends and/or the middle segment as consequence of an additive manufacturing process. Alternative or in addition, a heat sink or an additional heat sink may be releasable mounted to the conductor e.g. via heat sink fasteners.

The heat sink may be an integrated part that is monolithically formed with the conductor such as provided in one via an additive manufacturing process. It should be mentioned that the heat sink may be of a different type of material than the conductor. In such case it may be more correct to refer to a polylithic formed heat sink and conductor.

The conductor may comprise heat sink fasteners which may by a recess or protrusion used to attach an external or additional heat sink. Such heat sink fastener is advantageous in that not only does they facilitate an easy way of attaching a heat sink to the conductor 1, but they also ensure that the location of the removably attached heat sink is positioned exactly where it is intended. Such location is typically found from experience or simulation of layout of an electrical cabinet in which the conductor is installed.

The removable or additional heat sink may comprise a protruding part or recess part which is configure for engaging with the heat sink fastener. The structure of the heat sink may be so that it forces the recess/protrusion together or it may comprise a spring that ensures fastening of the heat sink to the conductor. In order to remove the heat sink a force may be applied a predetermined location of the heat sink to release the recess/protrusion from the heat sink fastener.

If the heat sink fastener is a protruding part, the removable heat sink may comprise a corresponding recess and if the heat sink fastener is a recess, the removable or additional heat sink may comprise a protruding part. Hence, the removable or additional heat sink may be connected by engaging the recess/protrusion of the heat sink with the corresponding heat sink fastener on one side of the conductor. Then push the removable or additional heat sink to the recess/protrusion of the conductor and the heat sink engages with the heat sink fastener on the other side of the conductor.

The heat sink fasteners may be of a protrusion type or a recess type. Other types than the illustrated may naturally also be used. Also, some that are surrounding the conductor i.e. e.g. a protrusion or recess may circumference the conductor 1.

As illustrated, an additional heat sink 13 is located between the component 12 and the heat sink 11. Such additional heat sink may serve the purpose of establishing a safety clearance between the component and the conductor/heat sink.

Depending on the safety clearance distance, it may be sufficient to provide a thermal conductive and non-electric conductive material between the component 12 and the conductor 1/heat sink 11. Examples of such material could be ceramic, plastic such as mylar, polycarbonate, etronax, etc. and rubber. Such materials are only used if not air is sufficient to comply with the requirements to safety clearance.

An additional heat sink 13 may in principle be located at any location of the conductor 1 independent of the location of a component. Hence, if for some reason it turns out that a location on a conductor is warmer than desired, an additional heat exchanger may be mounted to the conductor at that location. In this way the temperature may be reduced without any major adjustments in the electrical system or operation thereof. If no heat sink fasteners are available on the conductor, the additional heat sink may be connected to the conductor by cable binders, glued or similar to the conductor.

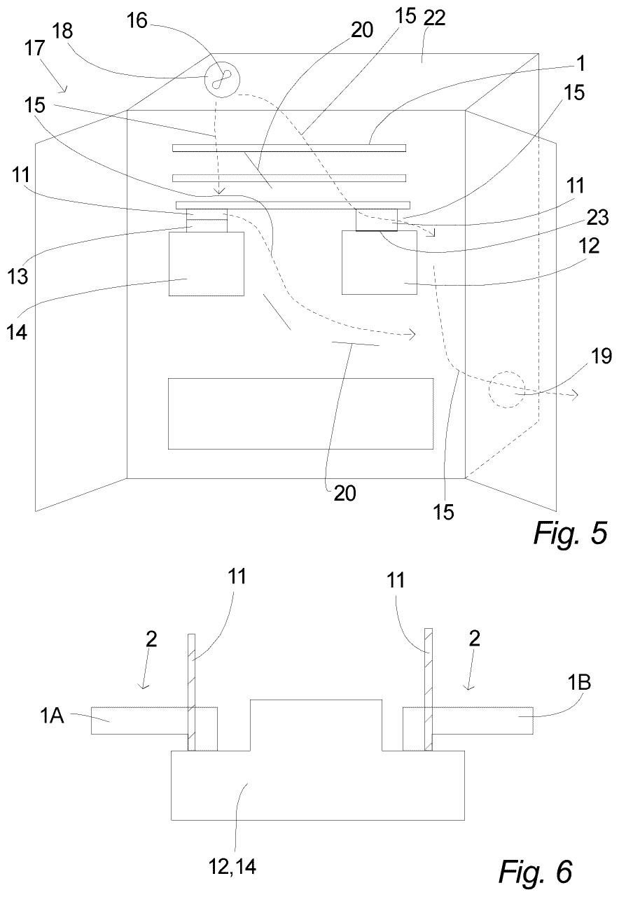

FIG. 5 illustrates an electrical cabinet 22 comprising a high-voltage and/or high-power electrical system 17. The system 17 comprising a plurality of conductors 1 of which one comprising an integrated heat sink 11 and power electronic components 14 such as power modules. During operation, the power electronic components 14 and maybe also other components generates heat which may at least partly be removed by a liquid cooling system. However, part of the generated heat may not be removed by the liquid cooling system. This heat has to be removed from the component by an air flow e.g. via a heat sink to ensure safe and stabile operation, especially heat generated by components that are not liquid cooled need a heat sink.

The system illustrated in FIG. 5 benefit from conductors 1 with incorporated heat sink 11. Thus, either a heat sink 11 of a conductor 1 connected electrically or not to a component 14, 12 is thermally connected to the component so as to remove heat from that component. In this way at least some heat sinks connected to components is no longer required and thus the system can be made more compact when using a conductor with integrated heat sink as suggested by the present invention.

Then to remove heat from the heat sink 11 an airflow 15 is established from an inlet 18 to an outlet 19 preferably via a fan 16. The fan 16 may be controlled by a signal from a temperature sensor received either directly from the sensor or from a controller which are communicating both with the sensor and with the fan 16.

As illustrated to ensure a correct flow of air 15 passing by the heat sinks 11, external (to the conductor) air guides 20 may be positioned in the cabinet 22 to ensure a desired direction of the air flow. Such external air guides 20 may be support by the cabinet, conductor or joint by the cabinet and conductor.

As illustrated and also mentioned above, the integrated heat sink may not be connected directly to the component 12, 14. Hence, to establish the desired safety clearance either a thermal conductive paste or an additional heat sink which is non-conductive may be used between the incorporated heat sink 11 and component 12, 14. In the specific embodiment illustrated in FIG. 5, the power module is spaced from the heat sink 11 by an additional heat sink 13 whereas the component 12 is only spaced from the heat sink by a thermic conductive material. This is because the power and/or voltage of the power module 14 is higher than in the component 12 and therefore the safety clearance is lower to the component 12 than to the power module 14. Hence, both the power module 14 and the component 12 may at least partly be cooled via the integrated heat sink 11 of the conductor 1.

FIG. 6 illustrates an embodiment of the invention where the integrated heat sink 11 is integrated at the end 2 of the conductor 1. This is just to illustrated that the heat sink 11 can be integrated at any location of the conductor 1. The reason why heat sink may be integrated at an end 2 of the conductor where the end 2 is connected to a component 12, 14 is that the conductor may be used as heat sink for the component 12, 14. Thus, if an integrated heat sink 11 is provide, this may reduce the required mass/surface of the conductor to ensure sufficient removal of heat from the component 12/14.

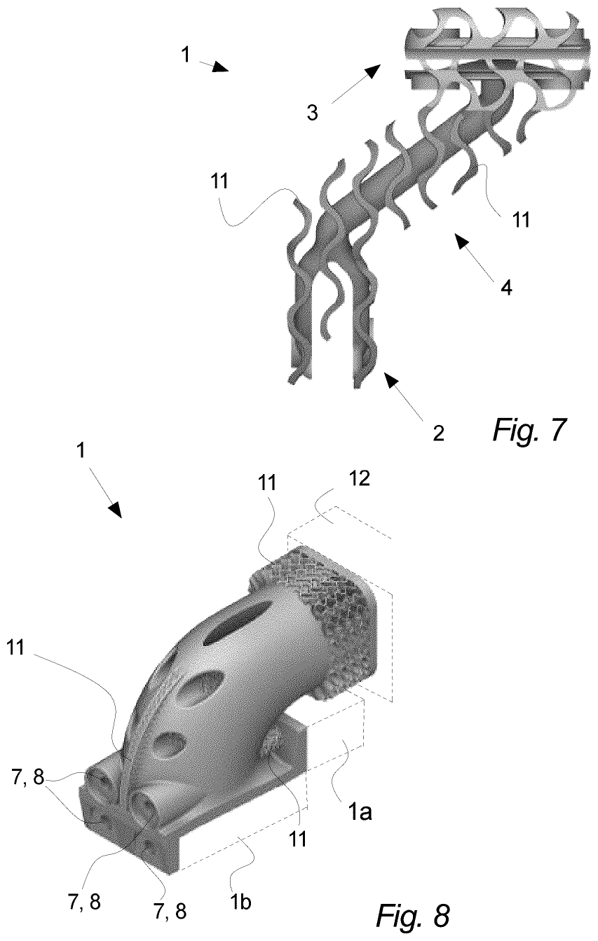

FIG. 7 illustrates a conductor with heat sinks 11 according to an embodiment of the invention. The heat sinks 11 are preferably monolithically formed with the conductor 1 taking into account the direction of air flow in the cabinet where the conductor is to be mounted. The wave like heat sinks 11 ensure optimal flow of air over the conductor i.e. both over the end segments 2, 3 and the middle segment 4.

The heat sinks 11 are forming predefined flow paths which may be at least partly defined by heat sinks which therefore also may function as air guides. The heat sinks 11 may be found on both sides of the conductor, hence the heat sinks may be plate like through which the conductor goes through.

FIG. 8 illustrates a conductor 1 which may be considered a connecting or transition conductor that is connected to a heat generating component 12 such as an electrical switch. Heat from the heat generating component may be guided from the end/contact surface of the conductor 1 connected to the switch via the internal channels and heat sinks 11. The heat sinks are located towards the end of the conductor connected to the heat generating component 12. In this way heat can be removed from that end/the heat generating component and into the open around the conductor. Further, a flow of air may be generated or provided through the channels defined between the walls constituting the heat sink inlet 14. which is assisting the removal of heat from the contact surface/conductor.

Two main busbars here denoted 1a, 1b may be connected to the conductor 1 via the terminals denoted 7, 8. Hence, as noted the internal channel 11 may also be used as bolt enclosures or guide i.e. when mounted, the internal channel 11 may house a bolt connecting the conductor 1 to a busbar.

Such busbar may also be considered a heat generating component 12. In FIG. 8 heat from the upper busbar la may also be removed via internal channels 11. More specific the internal channel 11 indicated by the pointer to an outer part of such internal channel denoted 11. The busbars la and 1b is indicated as two busbars but could one.

Note that to optimize heat distribution and heat exchange with surrounding air, the outer surface of the conductor 1 may also be equipped with heat sinks 11 as illustrated between the terminals 7, 8

From the above it is now clear that the invention relates to an electrical conductor comprising an integrated heat exchanger. This heat exchanger and thus the conductor may be located strategically in an electrical system to remove heat from components that are not otherwise cooled. In this way the conductor of the present invention with integrated heat sink is able to at cool down components such as power modules of an electrical system.

The invention has been exemplified above with the purpose of illustration rather than limitation with reference to specific embodiments. Details of specific embodiment have been provided in order to understand the aim of the invention. Please note, that detailed descriptions of well-known systems, devices, circuits, and methods have been omitted so as to not obscure the description of the invention with unnecessary details.

### LIST

1. Electrical conductor
2. First end
3. Second end
4. Middle segment
   a. First end
   b. Second end
5. Conductor branch
   a. Longitudinal conductor branch
   b. Transversal conductor branch
6. Air gap
   a. Longitudinal airgap (in X direction)
   b. Transversal airgap (in Y direction)
   c. Vertical airgap (in Z direction)
7. First terminal
8. Second terminal
9. Intersection point
10. Terminal hole
11. Heat sink
   a. Heat sink with air penetrating geometry
   b. Heat sink as a protrusion
   c. Heat sink as a recess
12. Heat generating component
13. Additional heat sink
14. Power electronic component
15. Flow of air
16. Fan
17. Electrical system
18. Air inlet
19. Air outlet
20. External air guides
21. Fasteners
22. Electric cabinet
23. Thermal paste

1. An electrical conductor comprising:
at least one first terminal that is a first end;
at least one second terminal that is a second end; and
a middle segment configured to space apart the first end from the second end, and to support conductance of an electric current between the at least one first terminal and the at least one second terminal,
wherein the middle segment includes at least one integrated heat sink.

2.-5. (canceled)

6. The electrical conductor according to claim 1, wherein the at least one integrated heat sink is the middle segment, and
wherein the middle segment is at least partly manufactured with an air penetrating geometry.

7. The electrical conductor according to claim 6, wherein the air penetrating geometry is one of:
gyroid, branch, bionic, web, honeycomb, and spongy.

8. (canceled)

9. The electrical conductor according to claim 1, wherein the middle segment with the at least one integrated heat sink is one monolithic geometry.

10.-11. (canceled)

12. The electrical conductor according to claim 1, wherein the middle segment is thermally connected with a heat generating component, and
wherein the thermal connection is at a first physical location on the heat generating component which is different from a second physical location on the heat generating component that is electrically connected to the electrical conductor.

13. The electrical conductor according to claim 12, wherein the at least one integrated heat sink is connected directly with the heat generating component

14. The electrical conductor according to claim 1, wherein the electrical conductor is configured to supply power to a component, and
wherein the middle segment is configured to remove heat from the component via the at least one integrated heat sink.

15. The electrical conductor according to claim 1, wherein the middle segment is thermally connected with a heat generating component via an additional heat sink.

16. The electrical conductor according to claim 15, wherein the additional heat sink is at least partly manufactured in a non-current conducting material.

17.-18. (canceled)

19. The electrical conductor according to claim 1, wherein at least part of the middle segment and the at least one integrated heat sink are at least partly manufactured simultaneously by an additive manufacturing process.

20. The electrical conductor according to claim 1, wherein the middle segment is monolithically formed in an electrically conductive material.

21. The electrical conductor according to claim 1, wherein the middle segment is monolithically formed in a first end of the middle segment with the first end the electrical conductor and monolithically formed in a second end of the middle segment with the second end of the electrical conductor.

22. The electrical conductor according to claim 1, wherein the middle segment further includes a plurality of conductor branches.

23. The electrical conductor according to claim 1, wherein the electrical conductor has a resonance vibration frequency of at least 5 Hz.

24.-26. (canceled)

27. A high power electrical system comprising:
an electrical cabinet including:
at least one heat generating component,
an air inlet, and
an air outlet; and
a plurality of electrical conductors at least one of the plurality of electrical conductors having a first end
wherein at least one of said plurality of electrical conductors includes at least one integrated heat sink,
wherein the at least one integrated heat sink is thermally connected to the at least one heat generating electrical component at a first location of the at least one heat generating electrical component,
wherein the first end of said electrical conductor is electrically connected to the at least one heat generating electrical component at a second location of the at least one heat generating electrical component, and wherein the first location and the second location are different locations.

28. The system according to claim 27, wherein a fan is configured to establish a flow of air between the air inlet and the air outlet, and
wherein at least one of the plurality of electrical conductors includes a middle segment in which the integrated heat sink is located, and wherein the integrated heat sink is located in the flow of air.

29. The system according to claim 28 , wherein the flow of air is directed to pass the middle segment by external air guides.

30. A method of producing an electrical conductor including at least one heat sink, the method comprising steps of:
providing a digital representation of the electrical conductor;
providing a first layer of electrically conductive material; and
providing a plurality of subsequent layers of the electrically conductive material thereby forming a first end, a middle segment, and a second end of the electrical conductor,
wherein the at least one heat sink is formed as an integrated part of the electrical conductor.

31. The method according to claim 30, wherein the electrical conductor and the at least one heat sink are integrated by an additive manufacturing process.

32. The method according to claim 30, wherein the heat sink is monolithically integrated as part of the first end, the second end, or the middle segment.
